(19) United States
(12) Patent Application Publication
(10) Pub. No.: US 2011/0266044 A1
(43) Pub. Date: Nov. 3, 2011

(54) Thin Film Circuit Board Device

(75) Inventor: Liang-Yuan Yang, Keelung City (TW)

(73) Assignee: Changshu Sunrex Technology Co., Ltd.

(21) Appl. No.: 12/771,464

(22) Filed: Apr. 30, 2010

(51) Int. Cl. H05K 1/11

(52) U.S. Cl. 174/262

(57) ABSTRACT

A thin film circuit board device includes a multi-layered circuit unit that includes an upper circuit layer, a lower circuit layer and an insulation layer. The upper circuit layer has at least one first contact part. The lower circuit layer is disposed below the upper circuit layer and has at least one second contact part. The insulation layer is disposed between the upper and lower circuit layers and has at least one through hole corresponding to the first and second contact parts. The pressurizing unit is attached to the multi-layered circuit unit so as to press the first and second contact parts against each other within the through hole to establish an electrical connection.

### BACKGROUND OF THE INVENTION

1. Field of the Invention

The invention relates to a circuit board, more particularly to a thin film circuit board device.

2. Description of the Related Art

A conventional thin film circuit board device includes an upper circuit layer, a lower circuit layer and an insulation layer disposed between the upper and lower circuit layers. In order to make electric connection between the upper and lower circuit layers, the upper circuit layer is formed with a first contact part. The lower circuit layer is formed with a second contact part beneath the first contact part. The insulation layer has a through hole corresponding to the first and second contact parts, and a conductive adhesive is used to glue the first and second contact parts via the through hole such that the upper and lower circuit layers are interconnected electrically. However, the adhesiveness of the conductive adhesive can degrade gradually, and in the long run, the upper and lower circuit layers separate from each other.

Accordingly, an improved thin film circuit board device in the prior art is provided with an upper circuit layers formed with a plurality of first contact parts, a lower circuit layer formed with a plurality of second contact parts beneath the first contact parts, an insulation layer formed with a plurality of through holes each registered with one of the first contact parts, and a conductive adhesive bonding the first contact parts to the respective second contact parts. Therefore, when separation occurs in one set of the first and second contact parts, electrical connection can still be established through the remaining first and second contact parts. Nevertheless, as the conductive adhesive is degradable, when the service period thereof increases, it is possible that all of the first and second contact parts separate from each other and disconnect the first and lower circuit layers.

### SUMMARY OF THE INVENTION

Therefore, the main object of the present invention is to provide a thin film circuit board device with upper and lower circuit layers which are interconnected electrically without using any adhesive material.

Accordingly, a thin film circuit board device of this invention includes a multi-layered circuit unit and a pressurizing unit.

The multi-layered circuit unit includes an upper circuit layer, a lower circuit layer and an insulation layer. The upper circuit layer is formed with an upper circuit having at least one first contact part. The lower circuit layer is disposed below the upper circuit layer and is formed with a lower circuit having at least one second contact part beneath the first contact part. The insulation layer is disposed between the upper and lower circuit layers and has at least one through hole corresponding to the first and second contact parts so that the first and second contact parts extend into the through hole.

The pressurizing unit is attached to the multi-layered circuit unit so as to press the first and second contact parts against each other within the through hole such that the first and second contact parts contact each other to accomplish electric connection.

The advantage of the present invention is that the pressurizing unit provides permanent electric connection between the upper and lower circuit layers by pressing the first contact part of the upper circuit layer tightly against the second contact part of the lower circuit layer.

### BRIEF DESCRIPTION OF THE DRAWINGS

Other features and advantages of the present invention will become apparent in the following detailed description of the preferred embodiments with reference to the accompanying drawings, of which:

FIG. 1 is an exploded perspective view of the first preferred embodiment of a thin film circuit board device according to the present invention;

FIG. 2 is a side sectional view of the first preferred embodiment;

FIG. 3 is a side sectional view of the second preferred embodiment of a thin film circuit board device according to the present invention; and

FIG. 4 is a side sectional view of the third preferred embodiment of a thin film circuit board device according to the present invention.

### DETAILED DESCRIPTION OF THE PREFERRED EMBODIMENTS

Before the present invention is described in greater detail with reference to the accompanying preferred embodiment, it should be noted herein that like elements are denoted by the same reference numerals throughout the disclosure.

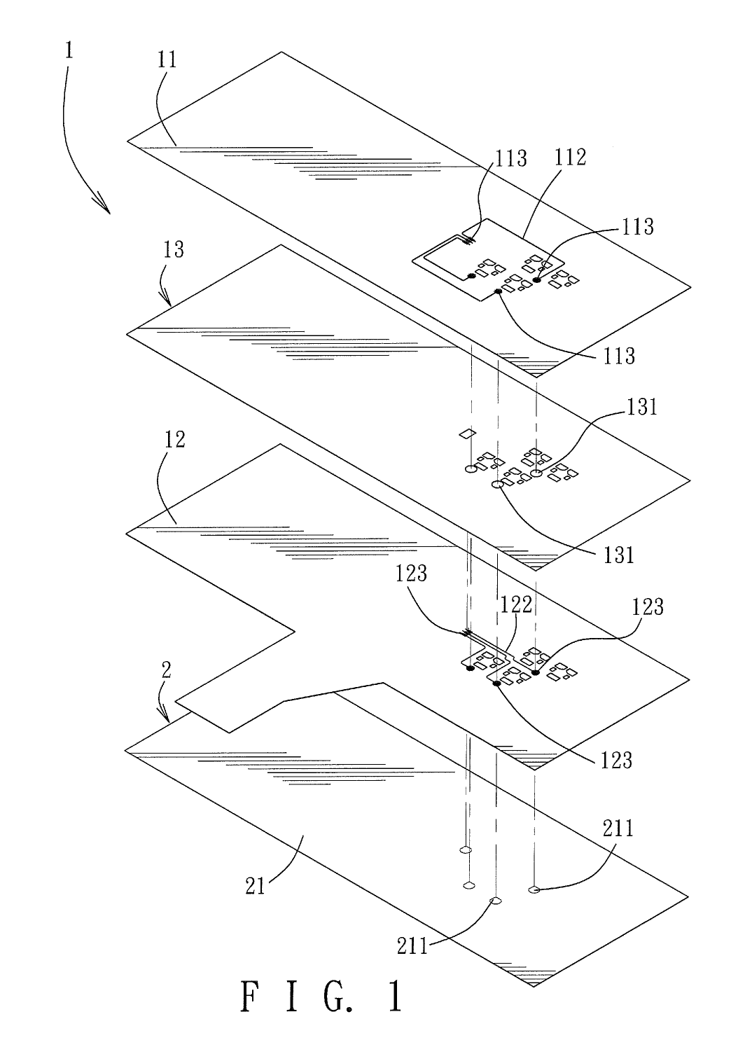

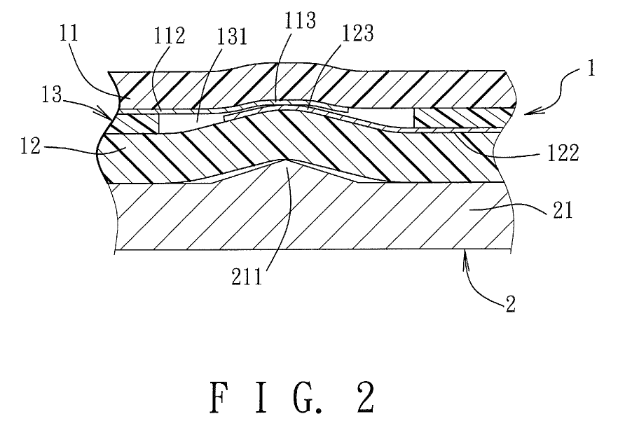

Referring to FIGS. 1 and 2, the first preferred embodiment of a thin film circuit board device according to the present invention is shown to include a multi-layered circuit unit 1 and a pressurizing unit 2.

The multi-layered circuit unit 1 includes an upper circuit layer 11, a lower circuit layer 12 and an insulation layer 13. The upper circuit layer 11 includes an upper circuit 112 that has a plurality of first contact parts 113, particularly, three first contact parts 113 in this embodiment. The lower circuit layer 12 is disposed below the upper circuit layer 11 and includes a lower circuit 122 that has a plurality of second contact part 123, particularly three second contact parts 123 in this embodiment. The insulation layer 13 is disposed between the upper and lower circuit layers 11, 12 and is formed with three through holes 131. 123 corresponding to the first and second contact parts 113, 123 so that the first and second contact parts 113, 123 extend into the respective through holes 131 and contact each other to make electric connection.

The pressurizing unit 2 is attached to the multi-layered circuit unit 1 and includes a first press layer 21 formed beneath a bottom face of the lower circuit layer 12, and has three first protrusions 211 registered with the respective through holes 131, respectively. The first protrusions 211 protrude upwardly and press the lower circuit layer 12 so that the lower circuit layer 12 deforms and projects toward the upper circuit layer 11, thereby pressing the second contact parts 123 against the respective first contact parts 113 through the respective through holes 131 of the insulation layer and establishing an electrical connection between the upper and lower circuit layers 11, 12.

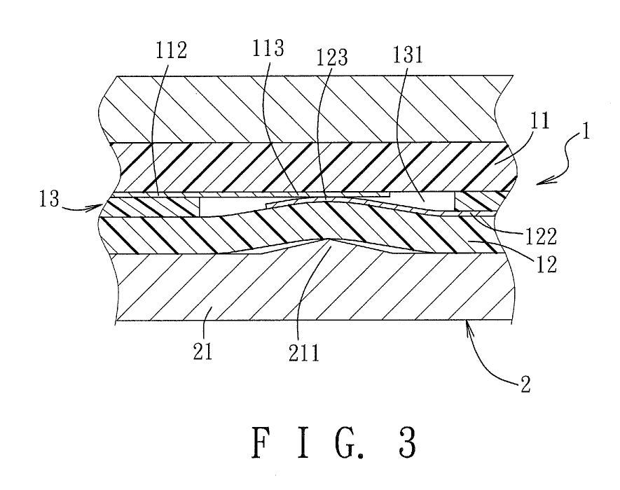

Referring to FIG. 3, the second preferred embodiment of this invention has an overall structure generally identical to the first preferred embodiment. The difference between the first and second preferred embodiment is that the pressurizing unit 2 further includes a second press layer 22 formed above a top face of the upper circuit layer 11 for pressing the upper circuit layer 11. Accordingly, an additional pressure is exerted on the upper and lower circuit layers 11, 12, and the first and second contact parts 113 can be pressed against each other more tightly.

While the first press layer 21 is formed beneath a bottom face of the lower circuit layer 12, and the second press layer 22 is formed above a top face of the upper circuit layer 11 in the above preferred embodiments, in practice, the first press layer 21 may as well be formed above a top face of the upper circuit layer 11, and the second press layer 22 may also be formed beneath a bottom face of the lower circuit layer 12 to pressurize the upper and lower circuit layers 11, 12.

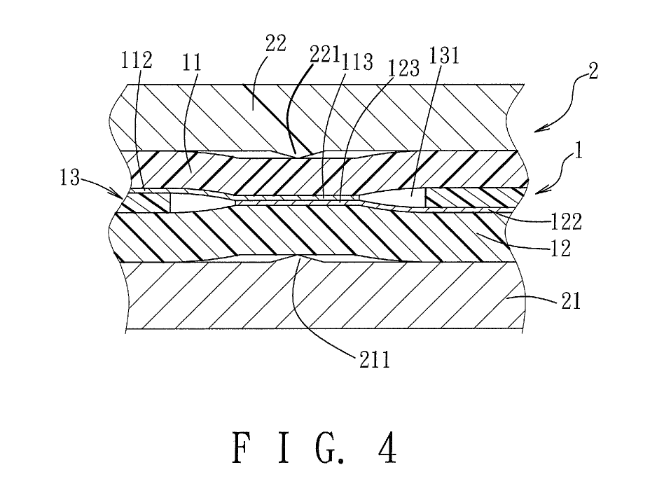

Referring to FIG. 4, there is shown a third preferred embodiment of this invention which differs from the second preferred embodiment in that the second press layer 22 is formed with second protrusions 221 that are registered with the through holes 131, respectively. The second protrusions 221 are used to press the first contact parts 113 against the respective second contact parts 123.

In sum, as the pressurizing unit 2 presses the first and second contact parts 113 and 123 of the upper and lower circuit layers 11, 12 against each other through the through holes 131 of the insulation layer 13 to establish electric connection between the upper and lower circuits 112 and 122, no adhesive material is needed to bond the first contact parts 113 to the respective second contact parts 123 according to the present invention.

While the present invention has been described in connection with what is considered the most practical and preferred embodiments, it is understood that this invention is not limited to the disclosed embodiments but is intended to cover various arrangements included within the spirit and scope of the broadest interpretation so as to encompass all such modifications and equivalent arrangements.

What is claimed is:

1. A thin film circuit board device comprising:
A multi-layered circuit unit that includes:
an upper circuit layer formed with an upper circuit having at least one first contact part;
A lower circuit layer disposed below said upper circuit layer and formed with a lower circuit having at least one second contact part beneath said first contact part; and
An insulation layer disposed between said upper and lower circuit layers and having at least one through hole corresponding to said first and second contact parts so that said first and second contact parts extend into said through hole; and
A pressurizing unit attached to said multi-layered circuit unit so as to press said first and second contact parts against each other within said through hole.

2. The thin film circuit board device of claim 1, wherein said pressurizing unit has a first press layer formed with at least one protrusion to press one of said first and second contact parts into said through hole and against the other one of said first and second contact parts.

3. The thin film circuit board device of claim 2, wherein said first press layer is formed beneath said lower circuit layer, and said protrusion presses upward said second contact part against said first contact part.

4. The thin film circuit board of claim 3, wherein said pressurizing unit further has a second press layer formed above said upper circuit layer.

5. The thin film circuit board of claim 4, wherein said second press layer has a protrusion that presses downward said first contact part against said second contact part.

6. The thin film circuit board of claim 2, wherein said first press layer is formed above said upper circuit layer, and said protrusion presses downward said first contact part against said second contact part.

7. The thin film circuit board of claim 6, wherein said pressurizing unit further has a second press layer formed beneath said lower circuit layer.

8. The thin film circuit board device of claim 7, wherein said second press layer has a protrusion that presses upward said second contact part against said first contact part.
